(19) United States
(12) Patent Application Publication
(10) Pub. No.: US 2007/0290221 A1
(43) Pub. Date: Dec. 20, 2007

(54) LIGHT EMITTING DIODE AND MANUFACTURING METHOD OF THE SAME

(75) Inventors: Chang-Da Tsai, Hsinchu (TW); Ching-Shih Ma, Hsinchu (TW)

Correspondence Address: WPAT, PC, 7225 BEVERLY ST., ANNANDALE, VA, 22003, US

(73) Assignee: OPTO TECH CORPORATION, Hsinchu (TW)

(21) Appl. No.: 11/748,802

(22) Filed: May 15, 2007

(30) Foreign Application Priority Data
Jun. 16, 2006 (TW) 095121721

(51) Int. Cl. H01L 33/00

(52) U.S. Cl. 257/99

(57) ABSTRACT

A light emitting diode includes a permanent substrate having a first portion and a second portion, and a chip attached on the first portion of the permanent substrate by a chip bonding technology. The chip includes at least one first electrode and a light emitting region. The manufacturing method comprises a step of mounting a single chip on the first portion of the permanent substrate by a chip bonding technology to overcome the fragility problem of an EPI-wafer.

### FIELD OF THE INVENTION

The present invention relates to a light emitting diode (LED) and a manufacturing method of the light emitting diode, and more particularly to a chip bonding light emitting diode and a manufacturing method of the chip bonding light emitting diode.

### BACKGROUND OF THE INVENTION

FIG. 1 depicts a diagram of a well-known AlGaInP quaternary light emitting diode. In the quaternary light emitting diode 100, a light emitting region 110 is grown on an n-doped GaAs substrate 102. The light emitting region 110 includes an n-doped AlGaInP layer 103, an AlGaInP active layer 104, a p-doped AlGaInP layer 105, and a p-doped GaP layer 106 arranged in the listed order. Moreover, a first electrode 108 is formed on the p-doped GaP layer 106 and a second electrode 109 is formed on the n-doped GaAs substrate 102. Typically, the AlGaInP active layer 104 is a double heterostructure active layer or a quantum well active layer.

Because the energy gap of the GaAs substrate 102 is around 1.42 eV, the cut off wavelength of the GaAs substrate 102 is around 870 nm, When a bias voltage is applied to the quaternary light emitting diode 100, the light, generated from the AlGaInP active layer 104 and having a wavelength less than 870 nm, will be absorbed by the GaAs substrate 102, thereby reducing the efficiency of the light emitting diode 100.

For fixing the above-described problem, a method of replacing the n-doped GaAs substrate by an optically transparent substrate is disclosed by the U.S. Pat. No. 5,502,316. Before the electrodes of the light emitting diode 100 depicted in FIG. 1 are formed, an etching procedure is first processed to remove the n-doped GaAs substrate 102. Moreover, an optically transparent substrate 122, e.g. an n-doped GaP substrate, a glass substrate, or a quartz substrate, is provided and bonded to the light emitting region 110 around a high temperature of 800-1000° C. via a wafer bounding technique. As depicted in FIG. 2, if the optically transparent substrate 122 is electrically conductive e.g. an n-doped GaAs substrate, a light emitting diode 120 can be manufactured by forming a first electrode 108 on the p-doped GaP substrate 106 and forming a second electrode 111 on a portion of the surface of the n-doped GaP substrate 122. According to the U.S. Pat. No. 5,502,316, the light-absorbing problem of the substrate can be fixed, so as the efficiency of the light emitting diode is enhanced.

FIGS. 3A to 3F depict the steps of manufacturing a light emitting diode according to a wafer bonding technique. As depicted in FIG. 3A, a single large-size substrate 102 is provided for the EPI process, wherein the substrate 102 is an n-doped GaAs substrate, also referred as a temporary substrate. In FIG. 3B, the light emitting region 110 is formed on the substrate 102. Then, the temporary substrate 102 is removed and only the light emitting region 110 is left as shown in FIG. 3C. In FIG. 3D, a large-size permanent substrate 122 is provided and bonded to the large-size light emitting region 110 via a wafer bonding technique. FIG. 3E depicts that a plurality of first electrodes 108 and a plurality of second electrodes 111 are formed on the light emitting region 110 and the permanent substrate 122, respectively. At last, as depicted in FIG. 3F, the above-described structure in FIG. 3E is cut into a plurality of light emitting diodes.

It is well understood that semiconductor material easily degrades at a high temperature. However, the wafer bonding technique is necessarily processed at a high temperature and the high temperature will degrade the light emitting region 110. In addition, because the large-size light emitting region 110 is bonded to the large-size permanent substrate 122, any uneven or particles adhered to the light emitting region 110 or the permanent substrate 122 may cause the failure in the wafer bonding step. Moreover, the light emitting region 110 is difficult to handle without breaking after the temporary substrate 102 is removed from and before the permanent substrate 122 is bonded to.

For fixing the above-described light-absorbing problem of the substrate, the U.S. Pat. No. 6,967,117 discloses another method for reflecting the light out the substrate. As depicted in FIG. 4A, a light emitting region 110 is formed on a temporary substrate 102, e.g. an n-doped GaAs substrate, wherein the light emitting region 110 sequentially includes an n-doped AlGaInP layer 103, an AlGaInP active layer 104, a p-doped AlGaInP layer 105, and a p-doped GaP layer 106. Moreover, a buffer layer 145 and a reflective layer 144 are formed sequentially on the light emitting region 110. As depicted in FIG. 4B, a permanent substrate 142 is provided and a diffusion barrier layer 143 is formed on the permanent substrate 142. By the wafer bonding technique, the reflective layer 144 is bonded to the diffusion barrier layer 143 at a high temperature, then, the temporary substrate 102 is removed and a first electrode 112 is formed on the n-doped AlGaInP layer 103 and a second electrode 113 is formed on the permanent substrate 142, as depicted in FIG. 4C. Because light can be efficiently reflected out from the substrate 142 by the reflective layer 144, the efficiency of the light emitting diode 140 can be enhanced significantly.

FIGS. 5A to 5G depict the steps of manufacturing a light emitting diode according to a wafer bonding technique disclosed in the U.S. Pat. No. 6,967,117. As depicted in FIG. 5A, a single large-size substrate 102 is provided for the EPI process, wherein the substrate 102 is a temporary substrate, e.g. an n-doped GaAs substrate. FIG. 5B depicts that the light emitting region 110 is grown on the substrate 102, and a buffer layer 145 and a reflective layer 144 are sequentially formed on the light emitting region 110. In FIG. 5C, a permanent substrate 142 is provided and a diffusion barrier layer 143 is formed on the permanent substrate 142. As shown in FIG. 5D, the diffusion barrier layer 143 is bonded to the reflective layer 144 via the wafer bonding technique. Then, in FIG. 5E, the substrate 102 is removed. FIG. 5F depicts that a plurality of first electrodes 112 and a second electrode 113 are formed on the light emitting region 110 and the permanent substrate 142, respectively. At last, as depicted in FIG. 5G, the above-described structure in FIG. 5F is cut into a plurality of light emitting diodes.

Alternatively, after the step in FIG. 5E is completed, an etching procedure can be processed to partially remove the light emitting region 110. The first electrode 112 and the second electrode 113 are formed on the n-doped AlGaInP layer 103 and the p-doped GaP layer 106, respectively, and this structure is then cut into a plurality of planar-electrode light emitting diodes as shown in FIG. 6.

In the above-described method, the wafer bonding is processed first, and then later the temporary substrate is removed and the electrodes are formed. However, even the problem resulted in the U.S. Pat. No. 5,502,316, a weak mechanical strength resulted by removing the substrate, can be avoided in this method, a poor reflection due to an alloy procedure during the formation of the first and the second electrodes on the bonded chips still occurs and it reduces the efficiency of the light emitting diode. Moreover, the etching procedure processed to the light emitting region 110 will reduce the surface area of the light emitting region 110, and current cannot uniformly travel through the light emitting diode 110, so as the efficiency of the light emitting diode is reduced.

The U.S. Pat. No. 6,221,683 discloses another method of manufacturing a light emitting diode. As depicted in FIG. 7A, a light emitting region 110 is formed on a temporary substrate 102 such as an n-doped GaAs, on which an n-doped AlGaInP layer 103, an AlGaInP active layer 104, a p-doped AlGaInP layer 105, and a p-doped GaP layer 106 are sequentially grown. Next, the temporary substrate 102 is removed, and first metallic contacts 162 are formed on the n-doped AlGaInP layer 103. As depicted in FIG. 7B, a permanent substrate 166 is provided and second metallic contacts 164 is formed on the permanent substrate 166. As depicted in FIG. 7C, a solder layer 163 is provided between the first metallic contacts 162 and the second metallic contacts 164, and the first metallic contacts 162 are alloyed with the second metallic contacts 164 via the wafer bonding technique. Then, a first electrode 170 is formed on the p-doped GaP layer 106 and a second electrode 172 is formed on the permanent substrate 166, wherein it is possible that the first electrode 170 and the second electrode are formed before the bonding step.

FIGS. 8A to 8G depict the steps of manufacturing a light emitting diode according to a wafer bonding technique disclosed in the U.S. Pat. No. 6,221,683. As depicted in FIG. 8A, a single large-size substrate 102 is provided for the EPI process, wherein the substrate 102 is a temporary substrate such as an n-doped GaAs substrate. FIG. 8B depicts that the light emitting region 110 is formed on the temporary substrate 102. FIG. 8C depicts that the temporary substrate 102 is removed and a plurality of first metallic contacts 162 are formed on the light emitting region 110. FIG. 8D depicts that a permanent substrate 166 is provided and a plurality of second metallic contacts 164 are formed on the permanent substrate 166. FIG. 8E depicts that a solder layer 163 is provided between the first metallic contacts 162 and the second metallic contacts 164, and the first metallic contacts 162 are alloyed with the second metallic contacts 164 via the wafer bonding technique. FIG. 8F depicts that a plurality of first electrodes 170 are formed on the light emitting region 110 and a second electrode 172 is formed on the permanent substrate 166. At last, FIG. 8G depicts that the above-described structure in FIG. 8F is cut into a plurality of light emitting diodes.

However, the above-mentioned problems, including that the light emitting region 110 is difficult to handle without breaking and the efficiency of the light emitting diode degrades during the alloy procedure, still occur.

### SUMMARY OF THE INVENTION

There, the present invention provides a chip bonding light emitting diode having a permanent substrate partially overlapped by a light emitting region of the chip bonding light emitting diode and achieving a better efficiency.

The present invention also provides a method for manufacturing a light emitting diode to overcome the light-absorbing problem and decreasing the broken wafer to increase the yield.

The present invention discloses a method of manufacturing a light emitting diode, comprising steps of: providing a temporary substrate; forming a light emitting region on the temporary substrate; forming a plurality of first electrodes on a first surface of the light emitting region; removing the temporary substrate; forming a plurality of ohmic contact dots, a reflective layer, a barrier layer, and a eutectic layer sequentially on a second surface of the light emitting region; cutting the resulting structure into a plurality of chips, wherein each chip includes at least one first electrode, a portion of the light emitting region, a plurality of ohmic contact dots, a portion of the reflective layer, a portion of the barrier layer, and a portion of the eutectic layer; providing a permanent substrate; and mounting the plurality of chips with the permanent substrate via a chip bonding technique to obtain a plurality of the light emitting diodes, wherein in each light emitting diode, the permanent substrate is partially covered by the chip.

Moreover, a light emitting diode is provided. It includes a permanent substrate having a first portion and a second portion; and a chip mounted on the first portion of the permanent substrate by a chip bonding technique and comprising at least one first electrode and a light emitting region.

In an embodiment, the permanent substrate is a submount made of a high heat conductive and non-electrical conductive material such as AlN or a high heat conductive metal material such as Cu. The material of the ohmic contact dot is Ge/Au alloy. The material of the reflective layer can be Au, Al, or Ag, or the reflective layer can be a combination of a metal oxide layer and a metal layer having a high reflectance, wherein the metal oxide layer can be served as a reflective layer due to different refraction indexes between the metal oxide and the light emitting diode. The metal oxide layer can avoid an inter-diffusion between the metal layer and the light emitting diode. The barrier layer is made of Pt, Ni, W, or Indium Tin Oxide having a high stability and a high melting point. The eutectic layer is made of Sn, SnAu, SnIn, AuIn, or SnAg alloy. The temporary substrate is an n-doped GaAs substrate.

In an embodiment, the light emitting region includes an n-doped AlGaInP layer, an AlGaInP active layer grown on the n-doped AlGaInP layer, a p-doped AlGaInP layer grown on the AlGaInP active layer, and a p-doped GaP layer grown on the p-doped AlGaInP layer.

In an embodiment, the AlGaInP active layer is a double heterostructure active layer or a quantum well active layer.

### BRIEF DESCRIPTION OF THE DRAWINGS

The above contents of the present invention will become more readily apparent to those ordinarily skilled in the art after reviewing the following detailed description and accompanying drawings, in which:

FIG. 1 is a cross-sectional diagram of an AlGaInP quaternary light emitting diode in the prior art.

FIG. 2 is a cross-sectional diagram of another AlGaInP quaternary light emitting diode in the prior art.

FIGS. 3A to 3F show the steps of manufacturing the light emitting diode in FIG. 2 via a known wafer bonding technique.

FIGS. 4A to 4C show the process of manufacturing a light emitting diode having a reflective layer in the prior art.

FIGS. 5A to 5G show steps of manufacturing a light emitting diode in FIG. 4 via a wafer bonding technique.

FIG. 6 is a cross-sectional diagram of another light emitting diode having a reflective layer in the prior art.

FIGS. 7A to 7C show the process of manufacturing a light emitting diode having a solder layer in the prior art.

FIGS. 8A to 8G show the steps of manufacturing the light emitting diode in FIG. 7 via a wafer bonding technique.

FIG. 9 is a cross-sectional diagram showing a preferred embodiment of a chip bonding light emitting diode according to the present invention.

FIGS. 10A to 10F show steps of manufacturing the light emitting diode in FIG. 9 via a chip bonding technique according to the present invention.

FIG. 11 is a diagram illustrating the light reflection paths in the light emitting diode according to the present invention when the metal layer is regarded as another reflective layer.

### DETAILED DESCRIPTION OF THE PREFERRED EMBODIMENT

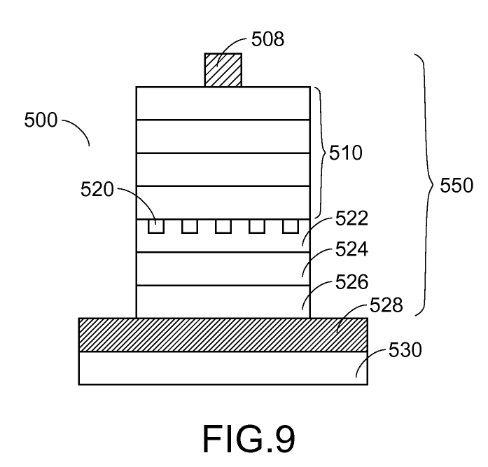

The present invention discloses a chip bonding light emitting diode for fixing the defects of the light emitting diode that is manufactured according to the wafer bonding technique. FIG. 9 is a cross-sectional diagram showing the structure of the chip bonding light emitting diode of the present invention. The chip bonding light emitting diode 500 includes a first electrode 508, a light emitting region 510, an ohmic contact dot 520, a reflective layer 522, a barrier layer 524, a eutectic layer 526, a metal layer 528 served as a second electrode, and a submount 530. The first electrode 508, the light emitting region 510, the ohmic contact dot 520, the reflective layer 522, the barrier layer 524 and the eutectic layer 526 can be regarded as a chip 550. The first electrode 508 and the metal layer 528 are configured as planar electrodes, and the submount 530 is a permanent substrate. Moreover, the surface area of the metal layer 528 is greater than the bottom surface area of the light emitting region 510.

For forming a planar electrode without reducing the efficiency of the light emitting diode, a large-size submount 530 is provided in the present invention, and a plurality of cut chips are placed on the submount 530 for the alloy procedure. The manufacturing procedures are described in the following.

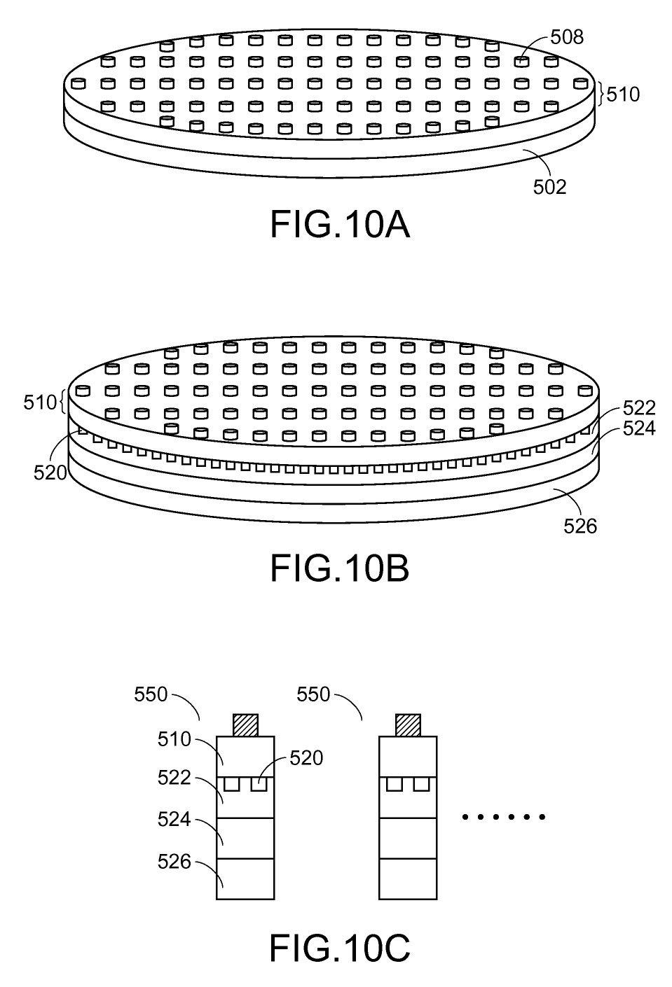

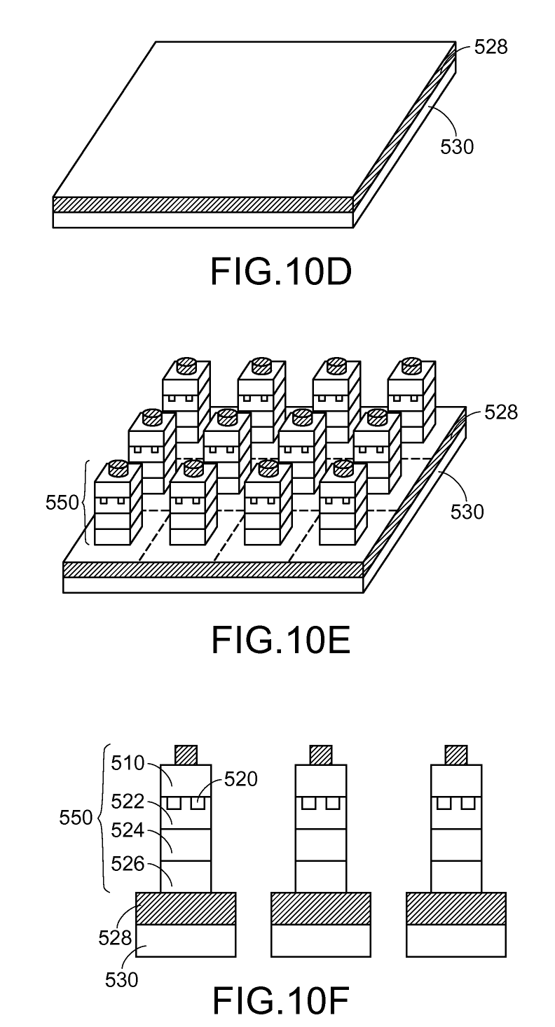

As depicted in FIG. 10A, an n-doped GaAs wafer is provided as a substrate 502, a light emitting region 510 is grown on the substrate 502, and a plurality of first electrodes 508 are formed on the light emitting region 510. The light emitting region 510 at least includes an n-doped AlGaInP layer, an AlGaInP active layer, a p-doped AlGaInP layer, and a p-doped GaP sequentially formed on the n-doped GaAs substrate 502. Typically, the AlGaInP active layer can be a double heterostructure active layer or a quantum well active layer. It is understood that the light emitting region 510 may vary in configurations according to different requirements. It is intended not to limit the structure of the light emitting region in the present invention.

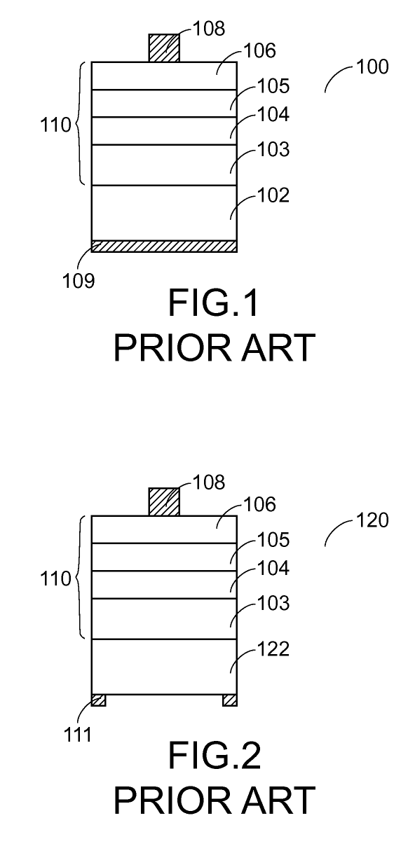

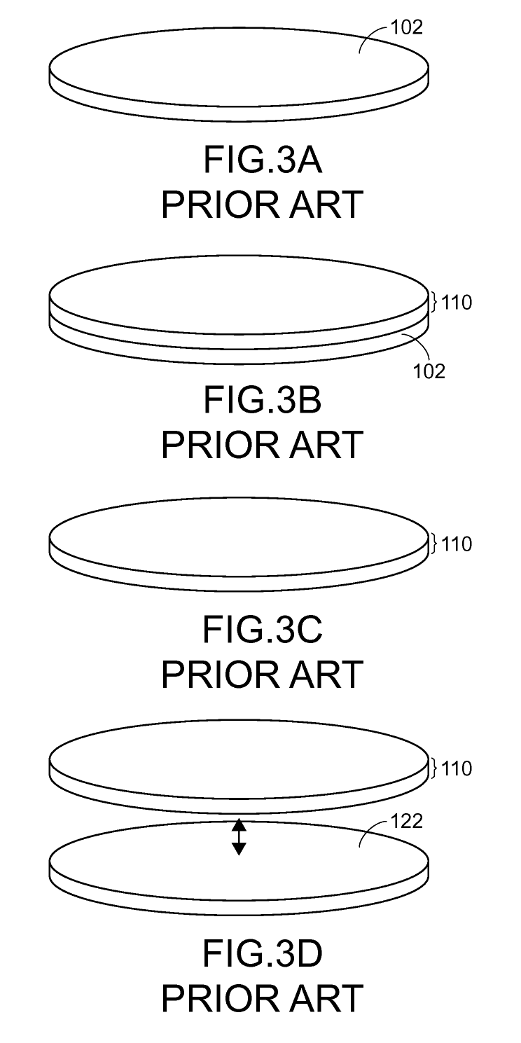

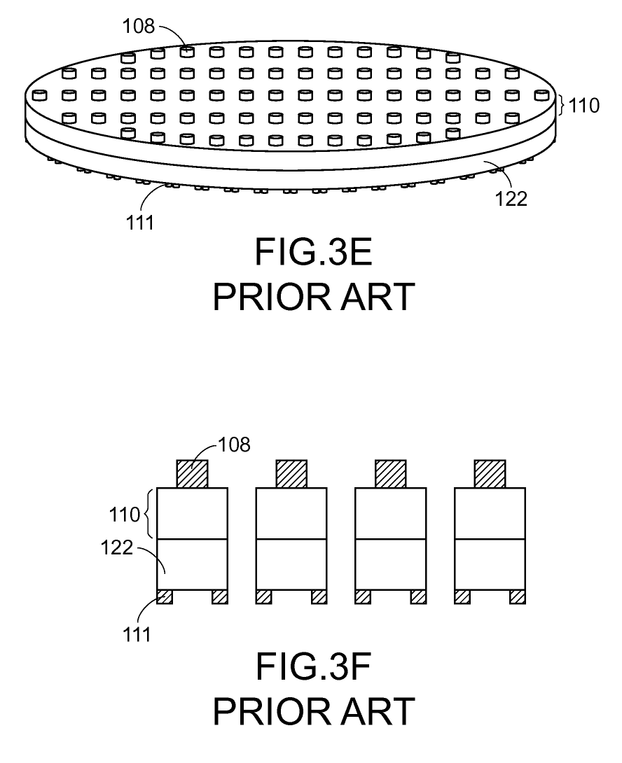

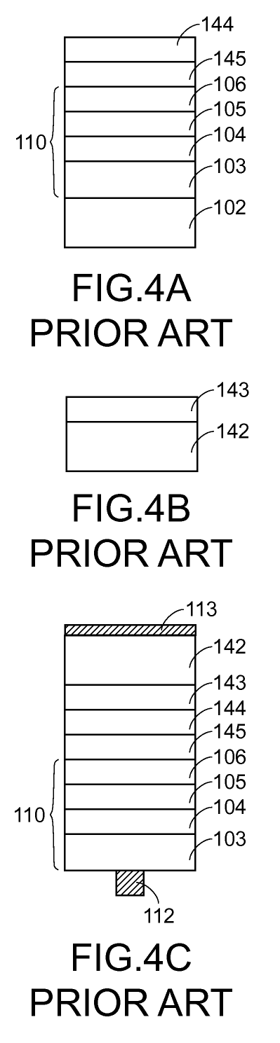

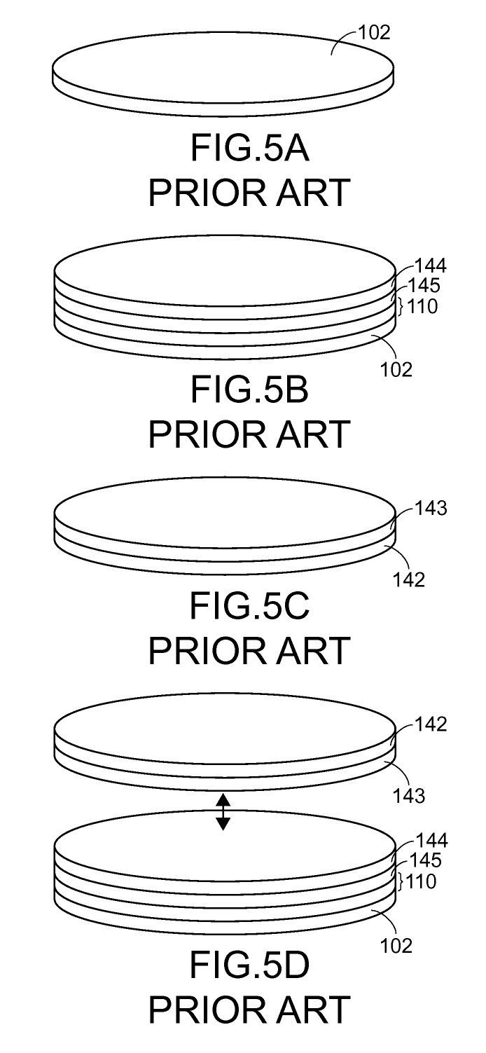

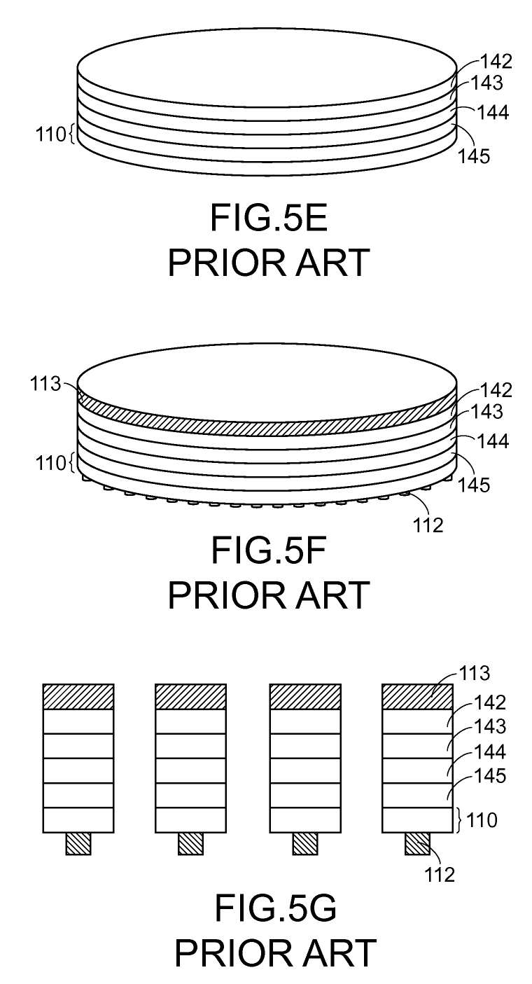

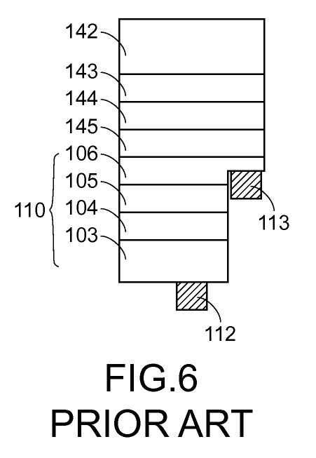

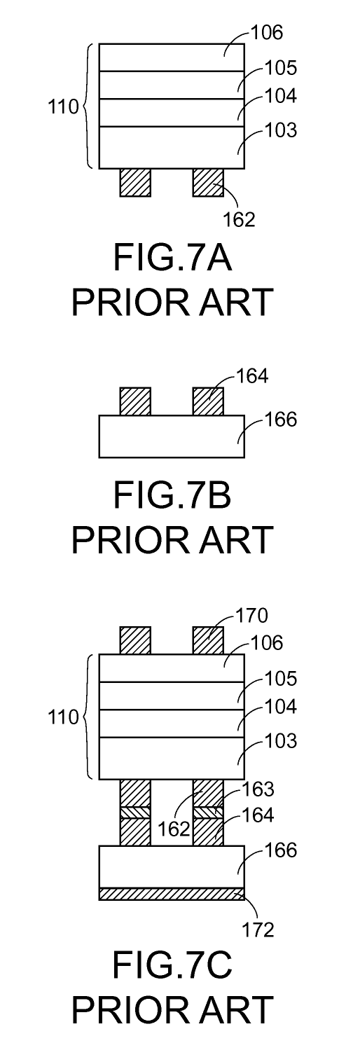

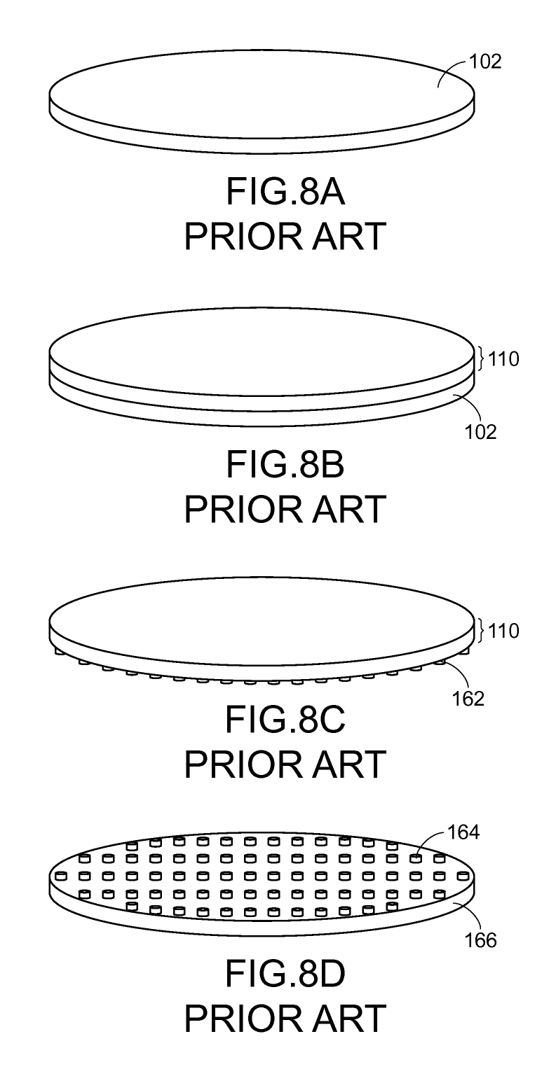

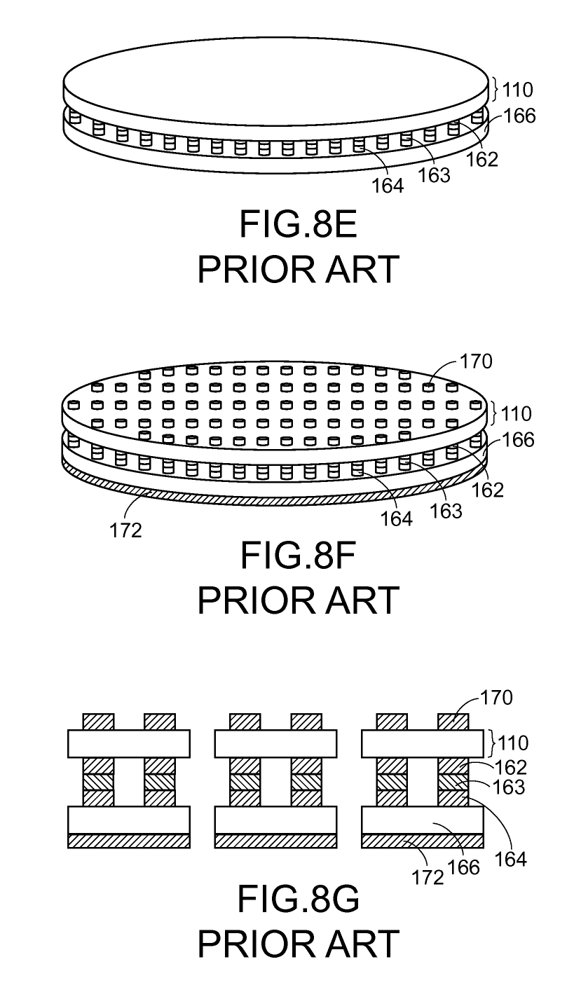

As depicted in FIG. 10B, after the n-doped GaAs substrate is removed, a plurality of ohmic contact dots 520, a reflective layer 522, a barrier layer 524, and a eutectic layer 526 are sequentially formed on the light emitting region 510. In an embodiment, the material of the ohmic contact dot 520 is Ge/Au alloy, and the reflective layer 522 is made of a metal having a high reflectance, e.g. Au, Al or Ag, or a combination of a metal oxide layer and a metal layer having a high reflectance. The metal oxide layer can be served as a reflective layer due to different refraction indexes between the metal oxide and the light emitting diode. Further, the metal oxide layer can avoid an inter-diffusion between the metal layer and the light emitting diode so as to keep the reflection. The barrier layer 524 is made of Pt, Ni, W, or Indium Tin Oxide having a high stability and a high melting point. The eutectic layer 526 is made of Sn, SnAu, SnIn, AuIn, or SnAg alloy having a melting point around 300° C. As depicted in FIG. 1C, the above-described structure in FIG. 10B is cut into a plurality of chips 550.

As depicted in FIG. 10D, a large-size submount 530 is provided, and a metal layer 528 is formed on the submount 530. As depicted in FIG. 10E, the eutectic layer 526 of each cut chip 550 is alloyed with the metal layer 528 around temperature 300° C. As depicted in FIG. 10F, the plurality of the light emitting diodes are obtained after cutting the submount 530 and the metal layer 528.

As depicted in FIG. 10F, the surface area of the cut metal layer 528 is greater than the bottom surface area of the chip 550. The metal layer 528 not covered by the chip 550 is served as a second electrode, and the other portion of the metal layer 528 is used for the alloy procedure and alloyed with the chip 550, thereby electrically connecting the metal layer 528 to the light emitting region 510 of the chip 550.

In addition, the submount 530 and the metal layer 528 can be cut first, and each chip 550 is alloyed with the cut metal layer 528. Therefore, the light emitting diode of the present invention is manufactured, wherein the metal layer 528 is partially covered by the chip 550.

In an embodiment, the metal layer is made of Au, Al, Ag, or a combination thereof. The submount is a permanent substrate made of a high heat conductive and non-electrical conductive material, e.g. AlN.

At last, the metal layer 528 is electrically connected to the light emitting region 510 by alloying the chips 550 with the submount 530 around temperature 300° C. to provide the chip bonding light emitting diode in FIG. 9.

In addition, the permanent substrate of the present invention can be a metal permanent substrate having high heat conductivity. The small-size chips can be directly alloyed with the metal permanent substrate without providing a metal layer on the permanent substrate. The metal permanent substrate can be a Cu substrate.

In addition, the reflective layer, provided by the present invention, is used for reflecting light out the permanent substrate.

In addition, the alloy procedure between the chips and the substrate of the present invention can be processed at a relatively low temperature without degrading the performance of the chips. The alloy temperature is under temperature 300° C. if the eutectic layer is made of Sn20Au80.

In addition, the chips are individually alloyed with the metal layer on the permanent substrate in the present invention, and the length, width, and height of the chips have the same scale level. Therefore, the wafer will not be broken due to insufficient mechanical strength. Even the large-scale light emitting region is broken after the GaAs temporary substrate is removed, the large-scale light emitting region can still be cut into a plurality of chips, and therefore, the yield of the chip bonding light emitting diode of the present invention is amazing.

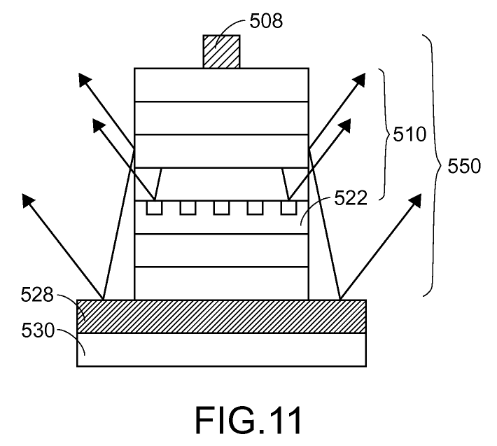

In addition, as depicted in FIG. 11, because the metal layer 528 on the permanent substrate 530 is partially covered by the chips 550, not only the reflective layer 522 within the chips 550 but also the exposed metal layer 528 can reflect the light generated from the light emitting region 510. Therefore, the efficiency of the light emitting diode is enhanced. Furthermore, the large area of the heat conductive submount is advantageous to heat dissipation, and it is particularly applicable to a high-power light emitting diode.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims, which are to be accorded with the broadest interpretation so as to encompass all such modifications and similar structures.

What is claimed is:

1. A method for manufacturing a light emitting diode, comprising steps of:
providing a temporary substrate;
forming a light emitting region on the temporary substrate;
forming a plurality of first electrodes on a first surface of the light emitting region;
removing the temporary substrate;
sequentially forming a plurality of ohmic contact dots, a reflective layer, a barrier layer, and a eutectic layer on a second surface of the light emitting region;
cutting the resulting structure into a plurality of chips, wherein each chip includes at least one first electrode, a portion of the light emitting region, a plurality of ohmic contact dots, a portion of the reflective layer, a portion of the barrier layer, and a portion of the eutectic layer;
providing a permanent substrate; and
mounting the plurality of chips with the permanent substrate via a chip bonding technique to obtain a plurality of the light emitting diodes, wherein in each light emitting diode, the permanent substrate is partially covered by the chip.

2. The method according to claim 1, wherein the permanent substrate is a metal permanent substrate.

3. The method according to claim 2, wherein the mounting step comprising a step of alloying the eutectic layer of the chips with the metallic permanent substrate.

4. The method according to claim 3, wherein an exposed portion of the metallic permanent substrate is served as a second electrode of the light emitting diode.

5. The method according to claim 1, wherein the permanent substrate is a submount.

6. The method according to claim 5, wherein the submount is an AlN Ceramic substrate.

7. The method according to claim 5, wherein the mounting step further comprising steps of:
forming a metal layer on the permanent substrate; and
alloying the eutectic layer of the chips with the metal layer, wherein the metal layer is partially covered by the chips.

8. The method according to claim 7, wherein an exposed portion of the metal layer is served as a second electrode of the light emitting diode.

9. The method according to claim 1, wherein the material of the ohmic contact dot includes a Ge/Au alloy.

10. The method according to claim 1, wherein the reflective layer is made of one selected from a group consisting of Au, Al, and Ag.

11. The method according to claim 1, wherein the barrier layer is made of one selected from a group consisting Pt, Ni, W, and Indium Tin Oxide.

12. The method according to claim 1, wherein the eutectic layer is made of one of SnAu or SnAg.

13. The method according to claim 1, wherein the temporary substrate is an n-doped GaAs substrate.

14. The method according to claim 1, wherein the light emitting region further includes:
an n-doped AlGaInP layer;
an AlGaInP active layer grown on the n-doped AlGaInP layer;
a p-doped AlGaInP layer grown on the AlGaInP active layer; and
a p-doped GaP layer grown on the p-doped AlGaInP layer.

15. The method according to claim 14, wherein the AlGaInP active layer is one of a double heterostructure active layer and a quantum well active layer.

16. A light emitting diode, including:
a permanent substrate having a first portion and a second portion; and
a chip mounted on the first portion of the permanent substrate by a chip bonding technique and at least comprising a first electrode and a light emitting region.

17. The device according to claim 16, wherein the permanent substrate is a submount.

18. The device according to claim 17, wherein the submount is an AlN Ceramic substrate.

19. The device according to claim 17, further comprising a metal layer formed between the chip and the permanent substrate, wherein the metal layer is partially covered by the chip, and a portion of the metal not covered by the chip is served as a second electrode.

20. The device according to claim 16, wherein the permanent substrate is a metallic permanent substrate.

21. The device according to claim 16, wherein the chip further comprises a plurality of ohmic contact dots, a reflective layer, a barrier layer, and a eutectic layer.

22. The device according to claim 21, wherein the material of the ohmic contact dots include a Ge/Au alloy.

23. The device according to claim 21, wherein the reflective layer is made of one selected from a group consisting of Au, Al, and Ag.

24. The device according to claim 21, wherein the barrier layer is made of one selected from a group consisting Pt, Ni, W, and Indium Tin Oxide.

25. The device according to claim 21, wherein the eutectic layer is made of one of SnAu or SnAg.

26. The device according to claim 16, wherein the light emitting region further includes:
an n-doped AlGaInP layer;
an AlGaInP active layer grown on the n-doped AlGaInP layer;
a p-doped AlGaInP layer grown on the AlGaInP active layer; and
a p-doped GaP layer grown on the p-doped AlGaInP layer.

27. The device according to claim 26, wherein the AlGaInP active layer is one of a double heterostructure active layer and a quantum well active layer.
